(19) United States
(12) Patent Application Publication
(10) Pub. No.: US 2026/0255888 A1
(43) Pub. Date: Aug. 27, 2026

(54) RESISTIVE RAM WITH MULTI-LAYER TUNGSTEN OXIDE CAP

(71) Applicants: International Business Machines Corporation, Armonk, NY (US); TOKYO ELECTRON LIMITED, Tokyo (JP)

(72) Inventors: Takashi Ando, Eastchester, NY (US); Kevin Wayne Brew, Niskayuna, NY (US); Paul Charles Jamison, Averill Park, NY (US); Steven Consiglio, Voorheesville, NY (US); Takaaki Tsunomura, Tokyo (JP); Kenichi Imakita, Albany, NY (US)

(21) Appl. No.: 18/776,221

(22) Filed: Jul. 17, 2024

(51) Int. Cl. H10N 70/00; H10B 63/00; H10N 70/20; H10W 20/41; H10W 20/42

(52) U.S. Cl. CPC H10N 70/8833; H10B 63/84; H10N 70/023; H10N 70/026; H10N 70/20; H10N 70/826; H10N 70/841; H10W 20/422; H10W 20/435

(57) ABSTRACT

An electrical memristive device has a layer structure. The later structure comprises two electrodes and a trilayer material arrangement that connects the two electrodes. The trilayer material arrangement may, for example, be sandwiched by the two electrodes, in direct contact therewith. The trilayer material arrangement includes an HfOₓ layer, where 1.3±0.1≤x<1.9±0.1, a WO_{y} layer in direct contact with the HfOₓ layer, where 1.9±0.1≤y<2.1±0.1 and a WO_{z} layer in direct contact with the WO_{y} layer, where 2.9±0.1≤z<3.1±0.1. One electrode is in contact with the HfOₓ layer while the other electrode is in direct contact with the WO_{z} layer. Optionally, the oxygen concentration of the WO_{z} layer can have a gradient which is lower when its contacting electrode is tungsten.

### BACKGROUND

The invention relates in general to the field of resistive random access memory (RRAM) including electrical memristive devices and apparatuses comprising such devices, notably artificial neural network hardware apparatuses, as well as methods of fabrication of such devices. In particular, the invention is directed to electrical memristive devices comprising a trilayer arrangement of layers of HfOₓ, WO_{y}, and WO_{z}.

Machine learning often relies on artificial neural networks (ANNs), which are computational models inspired by biological neural networks in human or animal brains. An ANN comprises a set of connected units or nodes, called artificial neurons. Signals are transmitted along connections (also called edges) between artificial neurons, similarly to synapses. That is, an artificial neuron that receives a signal processes it and then signals connected neurons. Connection weights (also called synaptic weights) are associated with the connections and nodes. Each neuron may have several inputs and a connection weight is attributed to each input (the weight of that specific connection). Such weights adjust as learning proceeds.

Neural networks are typically implemented in software. However, a neural network may also be implemented in hardware. For example, a resistive memory device can be used as a connection (synapse) between a pre-neuron and post-neuron, representing the connection weight in the form of device resistance. Multiple pre-neurons and post-neurons can be connected through a crossbar array of RRAMs, which naturally expresses a fully-connected neural network (e.g., a crossbar array structure for performing the synaptic interconnect operation), processing electrical or optical signals. A hardware-implemented ANN is a physical machine that clearly differs from a classic computer (general- or specific-purpose computer) in that it is primarily and specifically designed to implement an ANN (for training and/or inference purposes).

Running matrix operations (notably for back-propagation ANN algorithms) on crossbar arrays of memristors may potentially improve performance and efficiency of the hardware-implemented ANNs compared to software-implemented ANNs. The properties of the synaptic elements are key to the performance of the hardware-implemented ANN.

Synaptic elements used in neuromorphic hardware apparatuses typically comprise a memristive device, e.g., a phase-change memory (PCM) device, a resistive random-access memory (RRAM), or a magnetic random-access memory (MRAM). A memristor is a non-linear, two-terminal electrical component, which regulates the flow of electrical current and remembers its conductive state. Furthermore, the resistance of a memristor depends on the history of electric signals applied though the device. A memristor is non-volatile, insofar as it retains memory without power and does not change its state for small electrical signals when reading operation is performed at lower biases (V<0.3V).

Memristive devices are typically embodied as nanoscale memory devices. Recent advances in such memory devices are making this technology ever more relevant to industrial applications. For example, memristive devices can be used as building blocks of new computing paradigms, such as brain-inspired computing and memcomputing. In particular, and as noted above, such devices can be used in hardware implemented ANNs, such as crossbar array structures of resistive processing units. However, there are key challenges to overcome, such as the high programming power required, noise, and resistance drift of the memristors.

### SUMMARY

According to a first aspect, the present invention is embodied as an electrical memristive device (or memristor) having a layer structure. Including two electrodes, and a trilayer material arrangement between the two electrodes. The trilayer including a HfOₓ layer, in which 1.3±0.1≤x<1.9±0.1, a WO_{y} layer in direct contact with the HfOₓ layer, in which 1.9±0.1≤y<2.1±0.1, and a WO_{z} layer in direct contact with the WO_{y} layer, in which 2.9±0.1≤z<3.1±0.1.

According to another aspect, the invention is embodied as an electrical memristive device including two electrodes, in which one of the two electrodes comprises tungsten, a trilayer connecting the two electrodes. The trilayer including a HfOₓ layer, in which 1.3±0.1≤x<1.9±0.1, a WO_{y} layer in direct contact with the HfOₓ layer, in which 1.9±0.1≤y<2.1±0.1; and a WO_{z} layer in direct contact with the WO_{y} layer and in direct contact with the one of the two electrodes, the WO_{z} layer having an oxygen content in which “z” varies.

According to a final aspect, the invention is embodied as a method of fabricating an electrical memristive device includes providing a substrate and forming the following: a bottom electrode extending on top of the substrate, in electrical contact therewith, an HfOₓ layer extending on top of the bottom electrode, in electrical communication therewith, in which 1.3±0.1≤x<1.9±0.1, a WO_{y} layer in direct contact with the HfOₓ layer, in which 1.9±0.1≤y<2.1±0.1, a WO_{z} layer in direct contact with the WO_{y} layer, in which 2.9±0.1≤z<3.1±0.1, and a top electrode extending on top of the WO_{z} layer, so as for the top electrode to be in electrical communication with the WO_{z} layer.

### BRIEF DESCRIPTION OF THE DRAWINGS

These and other objects, features, and advantages of the present invention will become apparent from the following detailed description of illustrative embodiments thereof, which is to be read in connection with the accompanying drawings. The illustrations are for clarity in facilitating one skilled in the art in understanding the invention in conjunction with the detailed description. In the drawings:

FIG. 1 is a 2D cross-sectional view of a 2-terminal electrical memristive device in a vertical configuration, according to first embodiments;

FIG. 2 is a 2D cross-sectional view of a 2-terminal electrical memristive device in a planar configuration, according to second embodiments;

FIG. 3 is a 3D view of components of an apparatus configured as an artificial neural network hardware having a crossbar array structure with junctions including devices such as shown in FIG. 1, as in embodiments; and

FIG. 4 is a flowchart illustrating high-level fabrication steps of electrical memristive devices, according to embodiments.

The accompanying drawings show simplified representations of devices and apparatuses, or parts thereof, as involved in embodiments. Technical features depicted in the drawings are not necessarily to scale. Similar or functionally similar elements in the figures have been allocated the same numeral references, unless otherwise indicated.

Devices, apparatuses, and fabrication methods embodying the present invention will now be described, by way of non-limiting examples.

### DETAILED DESCRIPTION OF EMBODIMENTS OF THE INVENTION

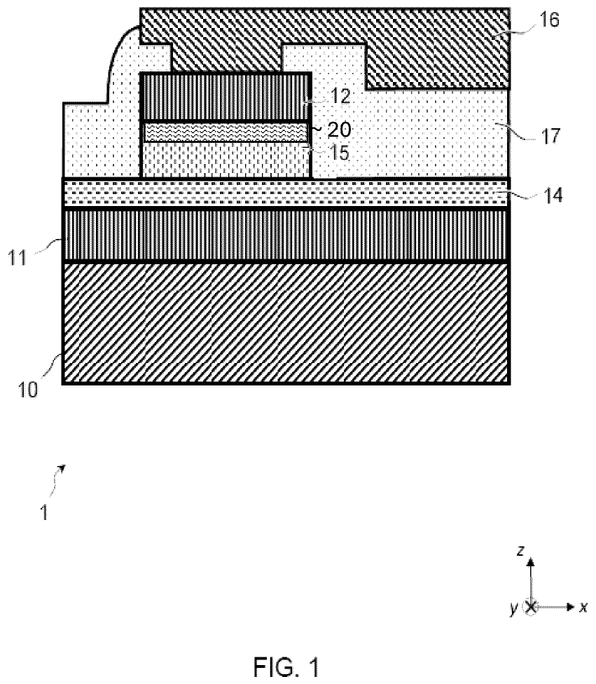

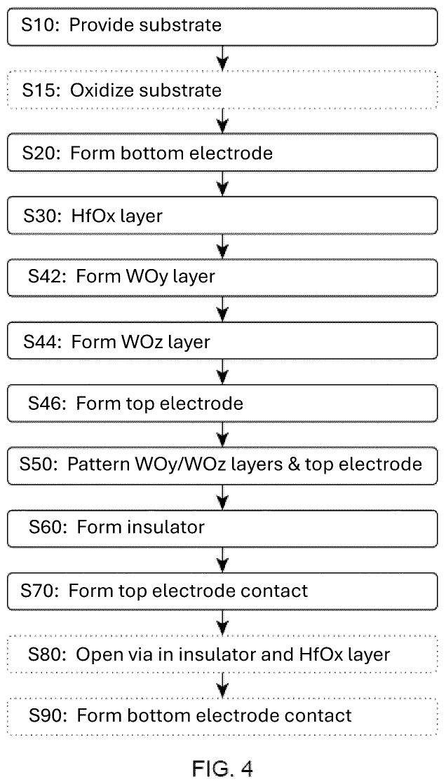

The present fabrication method and its variants are collectively referred to as the “present methods”. All references Sn refer to fabrication steps of the flowchart of FIG. 4, while numeral references pertain to physical parts or components of a device or an apparatus such as shown in FIGS. 1 to 3.

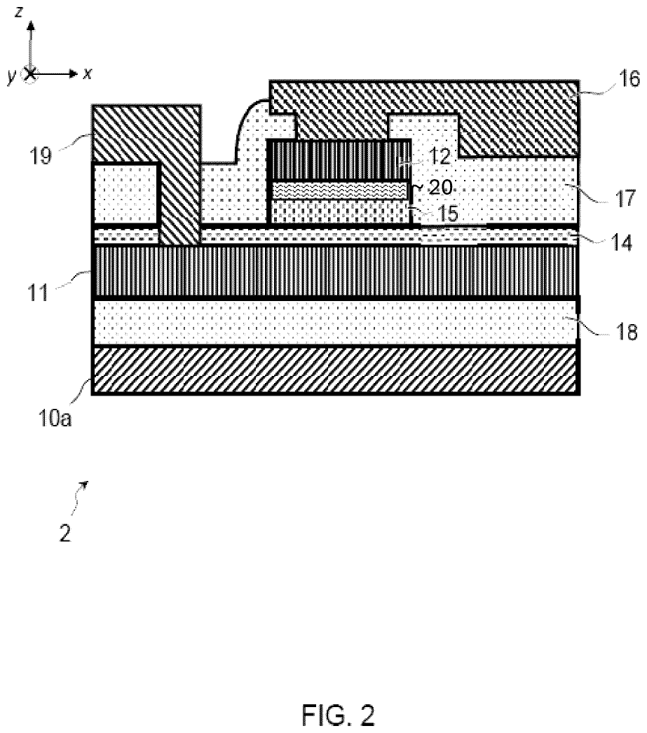

In reference to FIGS. 1 and 2, an aspect of the invention is first described, which concerns an electrical memristive device 1, 2, or memristor. Basically, the device has a layer structure, i.e., a stack of nanoscale layers of materials. The stack notably includes two electrodes 11, 12, which are formed as layers or layer portions. In addition, the layer structure includes a trilayer material arrangement that electrically connects the two electrodes. The trilayer arrangement includes an HfOₓ layer 14, a WO_{y} layer 15 and a WO_{z} layer 20, where the WO_{y} layer 15 is between and in direct contact with the HfOₓ layer 14, and the WO_{z} layer 20. Additionally, the HfOₓ layer 14, contacts one electrode while the WO_{z} layer 20 contacts the other electrode. Namely, in the HfOₓ layer 1.3±0.1≤x<1.9±0.1, while in the WO_{y} layer 1.9±0.1≤y<2.1±0.1 and finally in the WO_{z} layer 2.9±0.1≤z<3.1±0.1. For example, the trilayer arrangement may involve layers where 1.5±0.1≤x<1.7±0.1, and 1.9±0.1≤y<2.0±0.1, and 2.9±0.1≤z<3.0±0.1. The precision, 0.1, is given by the last digit. In other words, x is strictly less than 2, whereas y is strictly less than 2.3 and z is strictly less than 3.3, i.e., values corresponding to the expected stoichiometry of the layers.

X-ray photoemission spectroscopy, complemented by energy-dispersive X-ray spectroscopy (EDX), and transmission electron microscope (TEM) analyses, can be used to characterize the film compositions (x<1.9±0.1 and y<2.1±0.1 and z<3.1±0.1). As the present inventors have realized, the resulting devices appear to have markedly improved properties, especially for use as memories or as synaptic elements of hardware implemented artificial neural networks (ANNs). In particular, memristive devices based on WO_{z}/WO_{y}/HfOₓ trilayer arrangements as described above allow an improved performance to be obtained, be it in terms of analog resistance change, noise, or suppressed stochasticity of programming operations.

The actual reasons for such improvements remain partly unclear. The physical mechanisms involved are related to oxygen exchanges between the WO_{y} layer 15 and the conductive filaments formed in the HfOₓ layer 14. Complex phenomena are at work, which concern interface oxygen exchanges, drift through grain boundaries, defects, and valence change in the WO_{y} layer. The WO_{y} layer acts as a good ion conductor and has suitable non-volatile resistive switching characteristics. In addition, WO_{y} layer 15 is very sensitive to downstream air exposure/film depositions and difficult to maintain the chemical composition while at the same time, the HfOₓ/WO_{y} interface is critical to the analog switching. The integrity of the WO_{y} layer 15 and the HfOₓ/WO_{y} interface is maintained by WO_{z} layer 20 between WO_{y} layer 15 and the electrode 12 by serving as a barrier layer.

The layer stack can be fabricated using atomic layer deposition, sputtering, and rapid thermal annealing, as discussed later in reference to another aspect of the invention.

The present memristive devices can notably be used as resistive random-access memory (RRAM) devices. Compared to typical Ti/HfO₂ RRAM devices, the present devices result in more gradual transitions between the high resistance state (HRS) and the low resistance state (LRS). In addition, the present devices 1, 2 give rise to more tunable states (HRS and LRS) upon applying the programming signals (e.g., pulses of voltage biases). Moreover, no major drift <0.2% is observed for the different programmed states. In addition, the trilayer of the present invention suppresses unwanted oxygen exchange resulting in a more stable structure.

The devices are amenable to integration in hardware. In particular, the present devices 1, 2 can advantageously be used as synaptic elements in neuromorphic circuitry, so as to store and modify weights of synaptic elements in crossbar array structures.

All this is now described in detail, in reference to particular embodiments of the invention. To start with, each of the WO_{y} layer 15 and the WO_{z} layer 20 preferably has a polycrystalline structure. Such a polycrystalline arrangement was confirmed by TEM analyses. The polycrystalline structure gives rise to grain boundaries. Such grains, and their dimensions, are currently believed to play an important role in (and favorably contribute to) the properties of the present devices.

As seen in FIGS. 1 and 2, the HfOₓ layer 14, the WO_{y} layer 15 and the WO_{z} layer 20 are stacked along a stacking direction z, i.e., the direction perpendicular to the average plane of the trilayer material arrangement. In preferred embodiments, the polycrystalline WO_{y} layer 15 is processed in such a manner that the average dimensions of the grains of the WO_{y} layer 15 are larger than or equal to 3 nm along said stacking direction, while also being larger than or equal to 10 nm in the average plane of the trilayer material arrangement. In preferred embodiments, the polycrystalline WO_{z} layer 20 is processed in such a manner that the average dimensions of the grains of the WO_{z} layer 20 are larger than or equal to 3 nm along said stacking direction, while also being larger than or equal to 10 nm in the average plane of the trilayer material arrangement. The grain sizes are easily measured from, e.g., TEM images. The scale (integrated in the TEM image) can be used to measure the size of the grains. The same can be repeated for several TEM images (TEM is a local characterization technique

A polycrystalline material such as described above makes it possible for the WO_{y} layer 15 and the WO_{z} layer 20 to have an electrical resistivity p that is between 10⁻² and 10² ohm-cm (Ω·cm). That is, the resistivity of this layer may vary up to four orders of magnitude, which is appropriate for switching the device between an HRS and an LRS, as in applications discussed later. Note, the resistivity can notably be measured from Hall measurements, e.g., using the van der Pauw Method.

As opposed to the WO_{y} layer 15 and WO_{z} layer 20, which are polycrystalline, the HfOₓ layer 14 is preferably fabricated so as to be amorphous. This was confirmed by X-ray diffraction analyses; the X-Ray spectrum does not show any substantial diffraction peak. Moreover, no crystalline grains could be seen on TEM images in that case. Relying on an amorphous HfOₓ layer 14 appears to favorably impact the performance of the device 1, 2 in terms of both stability and endurance. In variants, a crystalline HfO layer can be used, although it is likely more difficult to obtain.

In embodiments, the electrodes 11, 12 are made of an inert metal. Such electrodes are preferably formed as layers or layer portions, as assumed in FIGS. 1 and 2. For example, each of the two electrodes 11, 12 may include or essentially consist of one or more metals such as Pt, W, and TiN. An inert metal refers to a metal that is not chemically active as opposed to metals such as aluminum. Advantageously, the electrode 12 which directly abuts the WO_{z} layer 20 can be tungsten. Even more advantageously, the oxygen content of the WO_{z} layer 20 can be graded such that the surface closer the tungsten electrode 12 has less oxygen while the surface closer to WO_{y} layer 14 has more oxygen. In such embodiments, at the WO_{y} end of the WO_{z} layer 20, the oxygen concentration is 2.9±0.1≤z<3.1±0.1 but the oxygen content can approach zero when it reaches the electrode end of the WO_{z} layer 20. This oxygen concentration gradient of the WO_{z} layer 20 with respect to the electrode 12 and WO_{y} layer 14 further suppress any degradation of the HfOₓ/WO_{y} interface which may occur during electrode 12 formation and helps maintain the chemical composition of the WO_{y} layer 14.

Each of the devices 1, 2 shown in FIGS. 1 and 2 involve two electrodes 11, 12, where the bottom electrode 11 is formed as a layer and the top electrode 12 is formed as a layer portion. Each of the two electrodes is in direct contact with the trilayer arrangement, on opposite sides thereof. In the pictured embodiments, the bottom electrode 11 is in direct contact with the HfOₓ layer 14 (below the latter), while the top electrode 12 is above and in direct contact with the WO_{z} layer 20, while WO_{y} layer 14 is the middle layer of the trilayer. That is, the electrode layers 11, 12 sandwich the trilayer arrangement 14, 15, and 20. However, the sandwich can also be reversed such the bottom electrode 11 is in direct contact with the WO_{z} layer 20, which is in direct contact with the WO_{y} layer 14, which is in direct contact with the HfOₓ layer 14, which is in direct contact with the top electrode 12.

The devices 1, 2 shown in FIGS. 1, 2 further comprise a substrate 10, 10a, which supports the bottom electrode 11. The substrate 10, 10a provides mechanical stability to the device 1, 2 and may additionally serve to ground the device 1 (via the electrode layer 11, as assumed in FIG. 1). The devices 1, 2 further include an electrical contact 16, which is in electrical communication with the top electrode 12. In the examples of FIGS. 1, 2, the electrical contact 16 is patterned on top of the electrode 12. Moreover, an electrically insulating layer 17 embeds the top electrode 12.

The electrically insulating layers 17, 18 typically comprise or consist of SiO₂. The electrical contact 16 (on top) partly coats the top electrode 12, which is otherwise embedded in the SiO₂ layer 17, to prevent undesired oxidization of this electrode 12. In variants, the electrically insulating layers 17, 18 may comprise another material, such as SiN.

The substrate 10 may for instance comprise highly doped silicon (as assumed in FIG. 1), such that electrical contact to the top electrode may be ensured via the doped silicon substrate in that case. The electrical signals applied flow from the top electrical contact 16 (e.g., made of tungsten) to the substrate 10. Electrical conductance values may be read in output of the device (via the electrode 12 and the substrate 10).

In variants, the device may be configured as a planar device 2, as illustrated in FIG. 2. In this case, the substrate 10a may include or essentially consist of silicon. Yet, an additional insulating layer 18 is provided on top of the substrate 10a, e.g., by oxidizing the later. As in FIG. 1, an electrical contact 16 is patterned on top of the top electrode 12 (e.g., TiN), which is otherwise immersed in SiO₂ 17. The device 2 further comprises an additional electrical contact 19, which ensures electrical communication with the bottom electrode 11. A via is formed through the electrically insulating layer 17 and the HfOₓ layer 14, so as for the electrical contact 19 to reach the bottom electrode 11. The contact 19 otherwise extends opposite to the substrate 10 with respect to the top electrode 12, so as to be contacted from the top.

The present devices 1, 2 are typically fabricated as nanoscale devices. The thickness of the WO_{z} layer 20 is preferably between 3 nm and 5 nm. The thickness of the WO_{y} layer 15 is preferably between 3 nm and 5 nm. In preferred embodiments, the thickness of the HfOₓ layer 14 is between 3 nm and 10 nm, while the thickness of each of the two electrodes 11, 12 is preferably between 3 nm and 5 nm. Still, one or each of the electrode layers 11, 12 may be made thicker; this, depending of the fabrication process used and the intended application. The thicknesses of the layers 11, 12, 14, 15, 20 are measured along the stacking direction z in the accompanying drawings. The lateral dimensions of the devices are typically larger than 20 nm; lateral dimensions are measured in directions parallel to the (x, y) plane in the accompanying drawings. The above thicknesses have been determined by EDX and confirmed by TEM analyses, as well as X-ray reflectivity measurements. Such dimensions are amenable to easy integration in apparatuses as described below.

Referring to the flowchart of FIG. 4, another aspect of the invention is now described, which concerns a method of fabrication of an electrical memristive device 1, 2 such as described above.

First, a substrate 10, 10a is provided, step S10. Next, various layers 11, 14, 15, 20, 12 are successively obtained S20-S50, as explained below.

A bottom electrode 11 is obtained (step S20), e.g., as a layer, which extends on top of the substrate 10, 10a, in electrical contact therewith. This layer 11 may possibly be in direct contact with the substrate 10, as assumed in FIG. 1. Else, an intermediate oxide layer 18 may be formed (step S15) on the substrate 10a, as in FIG. 2.

Next, an HfOₓ layer 14 is obtained, which extends on top of the bottom electrode 11 and in electrical communication therewith. As noted earlier, 1.3±0.1≤x<1.9±0.1. The HfOₓ layer 14 is preferably in direct contact with the electrode 11. Then, a WO_{y} layer 15 is obtained, where 1.9±0.1≤x<2.1±0.1. The layer 15 must be in direct contact with the HfOₓ layer 14, to enable oxygen exchanges as evoked earlier. Then, a WO_{z} layer 20 is obtained, where 2.9±0.1≤z<3.1±0.1. The layer 20 is in contact with the layer 14. The top electrode 12 is subsequently formed, e.g., as a layer portion. The electrode 12 extends on top of the WO_{z} layer 20, and so as for the top electrode 12 to be in electrical communication with the WO_{z} layer 20. The WO_{z} layer 20 is normally in direct contact with the electrode 12, as assumed in FIGS. 1, 2.

In preferred embodiments, each of the bottom electrode layer 11 and the HfOₓ layer 14 is obtained S20, S30 by atomic layer deposition (ALD). The HfOₓ layer is deposited S30 subsequently to the bottom electrode layer 11, e.g., immediately after, without exposing the bottom electrode layer 11 to air. The aim is to prevent oxidization of the bottom electrode 11, which preferably can comprise TiN, as noted earlier. The resulting HfOₓ layer 14 is normally amorphous and quasi-insulating, i.e., a small leakage current occurs across the layer for any applied (non-zero) voltage bias.

In an embodiment with a tungsten top electrode 12, the next three layers, WO_{y} layer 15, WO_{z} layer 20 and top electrode 12 (steps S30, S42 and S44, respectively) can be performed successively by sputtering tungsten with a different oxygen flow in each step (where the oxygen flow is zero in S44) at a temperature of 350-450 C. In embodiments in which the WO_{z} layer 20 is graded, the oxygen flow can be gradually reduced during S42. In embodiments in which the top electrode 12 is not tungsten, steps S30 and S42 remain the same in-situ sputtering process while at step S44 another sputtering chamber/target can be used or an ALD process used. Alternatively, in embodiments in which the WO_{z} layer 20 is not graded, tungsten can be deposited followed by rapid thermal annealing in an oxygen ambient at 350-450 C.

In step S50 the blanket layers of top electrode 12, WO_{z} layer 20 and WO_{y} layer 15 are lithographically etched and patterned to form a pillar which is preferably cladded S60 with an insulating material 17, e.g., SiO₂. If necessary, a trench may then be opened in the insulating material 17, so as to allow insertion of an electrical contact 16, for it to reach the top electrode 12. This electrical contact 16 is obtained by suitable deposition process at step S70, so as to be in direct contact with the top electrode 12. The contact 16 may further be patterned, if necessary, using standard processing techniques.

The above embodiments of the present fabrication method have been succinctly described, meaning only the high-level fabrication steps are described. However, the above steps may have to be complemented by usual lithographic steps, to precisely structure the layers, as usual in the art.

The fabrication process of planar devices 2 (such as shown as in FIG. 2) is essentially similar to the process used to fabricate a vertical device 1 as shown in FIG. 1, though additional steps S15, S80, S90 are required, as denoted by dotted frames in FIG. 4. Namely, one starts S10 with a silicon substrate 10a, which is then oxidized S15 to obtain a SiO₂ layer 18 on top of the silicon substrate 10a. Eventually, a via is opened S80 in the HfOₓ layer 14 and the SiO₂ layer 18 underneath, to allow the bottom electrode 11 to be accessed from the top. Finally, a deposition of an additional electrical contact 19 (e.g., of tungsten) is performed at step S90. Like the first contact 16, the second contact 19 may be further processed, so as to obtain a suitable contact pad for connecting the device 2.

Such fabrication processes can easily be inserted in a process for fabricating apparatuses such as described below.

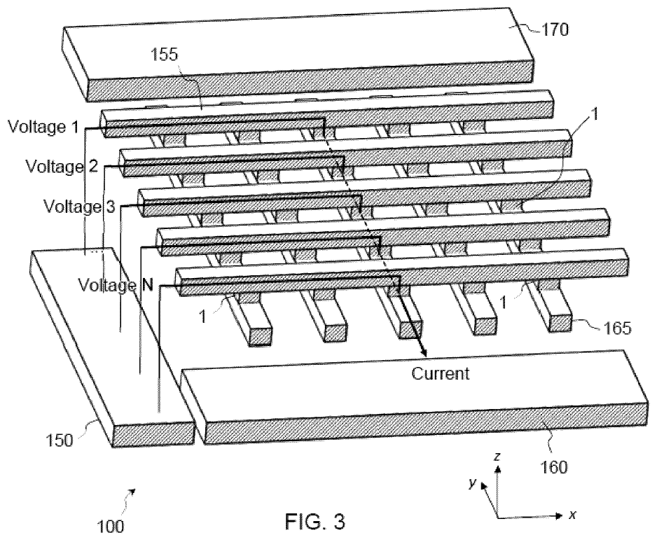

Referring to FIG. 3, a final aspect of the invention is now described, which concerns an apparatus 100. This apparatus comprises a plurality of electrical memristive devices 1, 2 such as described above. In addition, the apparatus further comprises an input circuit 150, which is connected to the electrical memristive devices 1, 2 via suitable electrical connectors 155, so as to be able to operate the devices 1, 2, in operation. Moreover, the apparatus further includes a readout circuit 160, also connected to the devices 1, 2, in output thereof. The readout circuit is configured to sense electrical signals from the devices 1, 2. In operation, such signals are impacted by current electrical conductances of the electrical memristive devices 1, 2. In general, such an apparatus 100 can be used as a memory.

Further components like a controller 170 (i.e., a programming circuit) and a processing unit (not shown) may be needed, for reasons that will become apparent later. Note, in FIG. 3, the input circuit 150, the readout circuit 160, and the controller 170 are typically meant to form part of a same processing core, together with the connecting structure formed by the electrical conductors 155 and 165. In variants, however, the components 150, 160, and 170 may be provided on separate chips, for example.

In embodiments, the apparatus 100 is configured as an ANN hardware, as assumed in FIG. 3. The apparatus 100 has a crossbar array structure, including input lines 155 and output lines 165. The input lines 155 and the output lines 165 are interconnected at junctions, as usual. In the present case, however, each junction includes an electrical memristive device 1 such as described earlier. The electrical memristive devices 1 are thus configured as synaptic elements of the ANN hardware. The device preferably has a vertical configuration (as shown in FIG. 1), to ease connections between the input lines and the output lines.

The operation of an apparatus 100, such as is shown in FIG. 3, is known per se. The synaptic update function is the most demanding task in training ANN hardware such as depicted in FIG. 3; it requires performant synaptic elements. Numerous electronic device concepts have been proposed to emulate synaptic behaviors, notably through non-volatile resistance changes, as also proposed herein. Synaptic devices based on filamentary conduction in nm thick HfOₓ layers are promising candidates to represent the synaptic weights. The arrangement in crossbar arrays of such RRAM devices enables analog synaptic signal processing between the ANN layers, where each layer may potentially contain a large number of neurons. HfOₓ-based RRAM devices are CMOS-compatible and have excellent potential in terms of gradual resistance change, device stability and reliability, power consumption, and scalability. In particular, a tight control of the gradual resistance change is essential for achieving a fine control and reliable change of the RRAM conductance.

In Ti/HfO₂ RRAM devices, for instance, the Ti film acts as an oxygen scavenging layer for the HfO₂ layer. After the formation of a filament, the interfacial redox reaction is difficult to precisely control by an external electrical stimulus; this results in abrupt programming characteristic of the HRS and the LRS. A typical DC set/reset behavior of a Ti/HfO₂ system show abrupt transitions between the LRS and HRS. A marked improvement can be obtained by replacing the Ti layer with a properly designed, trilayer of HfOₓ/WO_{y}/WO_{z} in which the WO_{y} layer 15 acts as an oxygen exchange layer with the HfOₓ layer 14, while the WO_{z} layer 20 acts as a barrier to protect the underlying layers of the trilayer from subsequent processes and exposure to air as proposed herein. The WO_{y} layer 14 crystalline matrix acts as a good ion conductor and exhibits suitable, non-volatile resistive switching characteristics. In addition, advantageously using a tungsten electrode 12 over the WO_{z} layer 20 as opposed to a titanium, which can be reactive, can maintain WO_{y} layer 14 composition. Compared to the Ti/HfO₂ RRAM, the RRAM based on a WO_{z}/WO_{y}/HfOₓ stack results in a more gradual HRS-to-LRS transition and in a more tunable HRS and LRS upon applying the programming voltage pulses. Moreover, no major drift <0.2% is observed for the different programmed states.

In the example of FIG. 3, the crossbar array structure is formed by N input lines 155 and M output lines 165. Only five input lines and five output lines are depicted in this example, for the sake of depiction. In practice, however, hundreds (or thousands) of input lines would likely be involved. Similarly, hundreds (or thousands) of output lines would likely be used. Certain applications may require that N differs from M. The input lines and the output lines are interconnected at the junctions, via N×M electronic devices, which include, each, a memristive device 1 such as described earlier.

The controller 170 may advantageously be an analog circuit. The controller is used to program the devices 1, via the input circuit 150, for the devices 1 to store values or, more exactly, to have properties (e.g., electrical conductance) interpretable as such values. The devices 1 may accordingly be programmed to store synaptic weights. The controller 170 may possibly include the input circuit 150 to couple input signals (e.g., apply voltage biases) into the input lines 155. In variants, a distinct analog circuit 150 (distinct from the controller 170) may be used to couple the input signals into the input lines 155, as assumed in FIG. 3.

The readout circuit 160 is configured to read out M output signals (e.g., electrical currents) obtained from the M output lines 165, in output of the devices 1. The readout is typically carried out according to a multiply-accumulate operation, which takes into account signals (e.g., currents) coupled into each of the input lines 155. As per the multiply-accumulate operations performed, values stored on each of the devices 1 impact the readout. The multiply-accumulate operation typically results in that signals coupled into the input lines are respectively multiplied by values stored on the devices 1 at the junctions.

Note, the architecture shown in FIG. 3 corresponds to a single layer of nodes of an ANN, rather than a multilayer network. This architecture may, in principle, possibly be expanded (or stacked) to achieve several connected layers (hence capable of representing a multilayer network). I.e., several crossbar array structures such as shown in FIG. 3 may possibly be interconnected via a core-to-core communication bus. In variants, the same ANN hardware is used to emulate each ANN layer. Yet, the crossbar array structure can be connected to a processor, e.g., including a digital processing unit, passing all the necessary information to successively execute the required layer operations. Note, each or any of the circuit 150-170 may possibly be embodied as a digital processing units, assuming that suitable convertors are provided to translate the signals. However, it is preferred to rely on analog circuits, for efficiency reasons.

The weights as stored on the devices 1 are constant for inference purposes (they benefit from the stability of the devices 1), whereas they need be iteratively reprogrammed for learning purposes, hence the need of updates, e.g., achieved through a back-propagation algorithm. The computation of the weight updates is normally performed by an external processing unit. The crossbar array structure(s) is used to perform all the basic operations (i.e., matrix vector products for the forward evaluation, products of transposed matrices and error gradient vectors for the backward evaluation, and vector outer products for updating weights), which involve large vector-matrix multiplications. During the learning phase, the controller (e.g., analog circuit) 170 is used to re-program the devices 1, so as to alter synaptic weights stored thereon according to the chosen learning algorithm. A structure 100 such as shown in FIG. 3 can serve for both learning and inference purposes.

For completeness, and beyond neural networks, we note that a crossbar array structure such as shown in FIG. 3 may also be used to perform matrix operations capturing decision tree operations. More generally, the present devices 1, 2 can be used as memory elements or electronic components in a variety of applications. In particular, such devices may possibly be co-integrated on silicon CMOS wafer containing circuitry.

In summary, According to a first aspect, the present invention is embodied as an electrical memristive device 1, 2 (or memristor) having a layer structure. Including two electrodes 11,12, and a trilayer material arrangement between the two electrodes. The trilayer including a HfOₓ layer 14, in which 1.3±0.1≤x<1.9±0.1, a WO_{y} layer 15 in direct contact with the HfOₓ layer 14, in which 1.9±0.1≤y<2.1±0.1, and a WO_{z} layer 20 in direct contact with the WO_{y} layer 15, in which 2.9±0.1≤z<3.1±0.1. The WO_{y} layer 15 can have a polycrystalline structure. In addition, the HfOₓ layer 14 and the WO_{y} layer 15 are stacked along a direction perpendicular to an average plane of the trilayer material arrangement. The average dimensions of grains of the WO_{y} layer 15 can be larger than or equal to 3 nm along the direction, and larger than or equal to 3 nm in the average plane of the trilayer material arrangement. In such cases, the WO_{y} layer 15 can have an electrical resistivity that is between 10⁻² ohm-cm and 10² ohm-cm. The HfOₓ layer 14 can be amorphous. Furthermore, each of the two electrodes 11,12 can include one or more of Pt, W, and TiN. The two electrodes 11, 12 comprise a bottom electrode 11 and a top electrode 12, each formed as a layer. The bottom electrode 11 is in direct contact with the HfOₓ layer 14, while top electrode 12 is in direct contact with the WO_{z} layer 20. A substrate 10, which can be silicon, supports the bottom electrode 11. An electrical contact 16 is in electrical communication with the top electrode 12 while an electrically insulating layer 17 embeds the top electrode 12. An additional electrical contact 19 is in electrical communication with the bottom electrode 11, through a via formed in the electrically insulating layer 17 and the HfOₓ layer 14, the additional electrical contact 19 extending opposite to the substrate 10 with respect to the top electrode 11. Exemplary thicknesses can be between 3 nm and 5 nm for each of the top electrode 12, bottom electrode 11, and WO_{y} layer 15, and can be between 3 nm and 10 nm for the HfOₓ layer 14. Technical benefits are more gradual transitions between the high resistance state (HRS) and the low resistance state (LRS). In addition, the present devices 1, 2 give rise to more tunable states (HRS and LRS) upon applying the programming signals (e.g., pulses of voltage biases). Moreover, no major drift <0.2% is observed for the different programmed states. In addition, the trilayer of the present invention suppresses unwanted oxygen exchange resulting in a more stable structure.

According to another aspect, the invention is embodied as an electrical memristive device 1,2 including two electrodes 11, 12, (in which one of the two electrodes comprises tungsten), a trilayer connecting the two electrodes, in which the trilayer includes a HfOₓ layer 14, in which 1.3±0.1≤x<1.9±0.1, a WO_{y} layer 15 in direct contact with the HfOₓ layer 14, in which 1.9±0.1≤y<2.1±0.1, and a WO_{z} layer 20 in direct contact with the WO_{y} layer 15 and in direct contact with the one of the two electrodes11, 12, the WO_{z} layer 20 having an oxygen content in which “z” varies. As the WO_{z} layer 20 is sandwiched between the one of the two electrodes 11, 12 and the WO_{y} layer 14, the WO_{z} layer 20 can have an electrode end adjacent the electrode and a WO_{y} layer end adjacent the WO_{y} layer 14. The oxygen content of the sandwiched WO_{z} layer 20 is greater at the WO_{y} layer end of the a WO_{z} layer compared to the electrode end of the WO_{z} layer. Or stated another way, “z” is greater at the WO_{y} layer end of the a WO_{z} layer compared to the electrode end of the WO_{z} layer. At the WO_{y} layer end of the a WO_{z} layer 2.9±0.1≤z<3.1±0.1. At the electrode end of the WO_{z} layer z<0.1. The technical benefit is further suppression of the interaction of the WO_{y} layer 14 with electrode thus maintaining the composition of the WO_{y} layer 14.

The electrical memristive device can further include an input circuit 150 connected to the electrical memristive device 1,2, so as to be able to operate the latter, and a readout circuit 160 connected to the electrical memristive device 1,2, the readout circuit 160 configured to sense electrical signals impacted by electrical conductance of the electrical memristive device 1,2, in operation. The electrical memristive device 1,2 can further include a crossbar array structure that includes an input line 155 and an output line 165 which are interconnected at junctions via the electrical memristive device 1,2, the latter configured as synaptic elements of the artificial neural network hardware. The technical benefit is using memristive devices as building blocks of new computing paradigms, such as brain-inspired computing and memcomputing.

A method of fabricating an electrical memristive device, including providing a substrate 10; and forming the following: a bottom electrode 11extending on top of the substrate 10, in electrical contact therewith, an HfOₓ layer 14 extending on top of the bottom electrode 11, in electrical communication therewith, where 1.3±0.1≤x<1.9±0.1, a WO_{y} layer in direct contact with the HfOₓ layer 14, wherein 1.9±0.1≤y<2.1±0.1, a WO_{z} layer 20 in direct contact with the WO_{y} layer 15, wherein 2.9±0.1≤z<3.1±0.1, and a top electrode 12 extending on top of the WO_{z} layer 20, so as for the top electrode 12 to be in electrical communication with the WO_{z} layer 20. The HfOₓ layer 14 can be obtained by atomic layer deposition; and each of the WO_{y} and WO_{z} layer can be obtained by sputtering tungsten in an oxygen ambient. The HfOₓ layer 14 can have a thickness of 3 nm to 10 nm, the WO_{y} layer 15 can have a thickness of 3 nm to 5 nm, and the WO_{z} layer 20 can have a thickness of 3 nm to 5 nm.

While the present invention has been described with reference to a limited number of embodiments, variants and the accompanying drawings, it will be understood by those skilled in the art that various changes may be made and equivalents may be substituted without departing from the scope of the present invention. In particular, a feature (device-like or method-like) recited in a given embodiment, variant or shown in a drawing may be combined with or replace another feature in another embodiment, variant or drawing, without departing from the scope of the present invention. Various combinations of the features described in respect of any of the above embodiments or variants may accordingly be contemplated, that remain within the scope of the appended claims. In addition, many minor modifications may be made to adapt a particular situation or material to the teachings of the present invention without departing from its scope. Therefore, it is intended that the present invention not be limited to the particular embodiments disclosed, but that the present invention will include all embodiments falling within the scope of the appended claims. In addition, many other variants than explicitly touched above can be contemplated. For example, other materials than those explicitly mentioned herein may be contemplated, notably for the substrates, the electrodes, and the insulating (dielectric) layers.

What is claimed is:

1. An electrical memristive device having a layer structure comprising:
two electrodes, and,
connecting the two electrodes, a trilayer material arrangement including:
an HfOₓ layer, wherein 1.3±0.1≤x<1.9±0.1;
a WO_{y} layer in direct contact with the HfOₓ layer, wherein 1.9±0.1≤y<2.1±0.1; and
a WO_{z} layer in direct contact with the WO_{y} layer, wherein 2.9±0.1≤z<3.1±0.1.

2. The electrical memristive device according to claim 1, wherein
the WO_{y} layer has a polycrystalline structure.

3. The electrical memristive device according to claim 2, wherein
the HfOₓ layer and the WO_{y} layer are stacked along a direction perpendicular to an average plane of the trilayer material arrangement; and
the average dimensions of grains of the WO_{y} layer are
larger than or equal to 3 nm along said direction, and
larger than or equal to 3 nm in said average plane of the trilayer material arrangement.

4. The electrical memristive device according to claim 3, wherein
the WO_{y} layer has an electrical resistivity that is between 10⁻² ohm-cm and 10² ohm-cm.

5. The electrical memristive device according to claim 3, wherein
the HfOₓ layer is amorphous.

6. The electrical memristive device according to claim 1, wherein
each of the two electrodes comprises one or more of Pt, W, and TiN.

7. The electrical memristive device according to claim 1, wherein
the two electrodes comprise a bottom electrode and a top electrode, each formed as a layer,
the bottom electrode is in direct contact with the HfOₓ layer, while top electrode is in direct contact with the WO_{z} layer; and
the electrical memristive device further comprises:
a substrate supporting the bottom electrode;
an electrical contact in electrical communication with the top electrode; and
an electrically insulating layer embedding the top electrode.

8. The electrical memristive device according to claim 7, wherein
the substrate comprises silicon;
the electrical memristive device further comprises an additional electrical contact in electrical communication with the bottom electrode, through a via formed in the electrically insulating layer and the HfOₓ layer, the additional electrical contact extending opposite to the substrate with respect to the top electrode.

9. The electrical memristive device according to claim 1, wherein
a thickness of the WO_{y} layer is between 3 nm and 5 nm.

10. The electrical memristive device according to claim 9, wherein
a thickness of the HfOₓ layer is between 3 nm and 10 nm.

11. The electrical memristive device according to claim 10, wherein
a thickness of one or each of the two electrodes is between 3 nm and 5 nm.

12. An electrical memristive device comprising:
two electrodes, wherein one of the two electrodes comprises tungsten;
a trilayer connecting the two electrodes, wherein the trilayer comprises:
an HfOₓ layer, wherein 1.3±0.1≤x<1.9±0.1;
a WO_{y} layer in direct contact with the HfOₓ layer, wherein 1.9±0.1≤y<2.1±0.1; and
a WO_{z} layer in direct contact with the WO_{y} layer and in direct contact with the one of the two electrodes, the WO_{z} layer having an oxygen content in which “z” varies.

13. The electrical memristive device according to claim 12, further comprising:
an electrode end of the WO_{z} layer; and
a WO_{y} layer end of the a WO_{z} layer;
wherein “z” is greater at the WO_{y} layer end of the a WO_{z} layer compared to the electrode end of the WO_{z} layer.

14. The electrical memristive device according to claim 13, wherein at the WO_{y} layer end of the a WO_{z} layer2.9±0.1≤z<3.1±0.1.

15. The electrical memristive device according to claim 13, wherein at the electrode end of the a WO_{z} layer z<0.1.

16. The electrical memristive device according to claim 13, further comprising:
an input circuit connected to the electrical memristive device, so as to be able to operate the latter, in operation; and
a readout circuit connected to the electrical memristive device, the readout circuit configured to sense electrical signals impacted by electrical conductance of the electrical memristive device, in operation.

17. The electrical memristive device according to claim 16, further comprising:
a crossbar array structure that includes an input line and an output line, and
the input line and the output line of the crossbar array structure are interconnected at junctions via the electrical memristive device, the latter configured as synaptic elements of the artificial neural network hardware.

18. A method of fabricating an electrical memristive device, the method comprising
providing a substrate; and
obtaining
a bottom electrode extending on top of the substrate, in electrical contact therewith;
an HfOₓ layer extending on top of the bottom electrode, in electrical communication therewith, where 1.3±0.1≤x<1.9±0.1;
a WO_{y} layer in direct contact with the HfOₓ layer, wherein 1.9±0.1≤y<2.1±0.1;
a WO_{z} layer in direct contact with the WO_{y} layer, wherein 2.9±0.1≤z<3.1±0.1; and
a top electrode extending on top of the WO_{z} layer, so as for the top electrode to be in electrical communication with the WO_{z} layer.

19. The method according to claim 18, wherein
the HfOₓ layer is obtained by atomic layer deposition; and
each of the WO_{y} and WO_{z} layer are obtained by sputtering tungsten in an oxygen ambient.

20. The method according to claim 18, wherein
the HfOₓ layer has a thickness of 3 nm to 10 nm;
the WO_{y} layer has a thickness of 3 nm to 5 nm; and
the WO_{z} layer has a thickness of 3 nm to 5 nm.
